(19) United States
(12) Patent Application Publication
(10) Pub. No.: US 2014/0030435 A1
(43) Pub. Date: Jan. 30, 2014

(54) EVAPORATION UNIT AND VACUUM COATING APPARATUS

(71) Applicants: Stefan Hein, Blankenbach (DE); Gerd Hoffmann, Bruchkoebel (DE)

(72) Inventors: Stefan Hein, Blankenbach (DE); Gerd Hoffmann, Bruchkoebel (DE)

(73) Assignee: APPLIED MATERIALS, INC., Santa Clara, CA (US)

(21) Appl. No.: 13/990,311

(22) PCT Filed: Dec. 1, 2010
(86) PCT No.: PCT/EP2010/068661

§ 371 Date: Oct. 11, 2013

(51) Int. Cl. C23C 14/24

(52) U.S. Cl. CPC C23C 14/24
USPC 427/255.5; 118/722

(57) ABSTRACT

Vacuum coating apparatus for coating a web includes a first rotatable coating drum and a second rotatable coating drum disposed parallel to the first drum with a gap formed between the first and the second coating drums for transporting at least one web. A first evaporator has at least one evaporation source for generating a first evaporation beam, wherein the first evaporator is arranged next to the first coating drum. A second evaporator has at least one evaporation source for generating a second evaporation beam, wherein the second evaporator is arranged next to the second coating drum. The first and the second evaporators are inclined relative to each other.

### BACKGROUND OF THE INVENTION

1. Field of the Invention

Embodiments described herein relate to a vacuum coating apparatus for coating a web. More particularly, embodiments of vacuum coating apparatuses having at least one evaporation source and at least two coating drums are described. Further embodiments relate to vacuum coating apparatuses having at least two coating drums and at least two evaporation sources which are inclined relative to each other. Further embodiments relate to an evaporation unit having evaporation sources which are inclined relative to each other.

2. Description of the Related Art

Coating apparatuses are used for coating webs such as foils or films with a material overlay. A coating apparatus includes an evaporation source directed towards a coating drum transporting the web through a deposition zone formed between the evaporation source and the coating drum. Material evaporated from the evaporation source forms an “evaporation beam” having a certain opening angle so that the evaporated material spreads. To restrict the deposition of evaporated material onto the web and to avoid deposition onto other regions of the coating apparatus shielding means are provided, which cover the regions to be protected. These shielding means need to be cleaned at regular intervals. Furthermore, a significant amount of the evaporated material is deposited onto these shielding means and is therefore wasted which reduces the yield.

Therefore, there is a need for improving vacuum coating apparatuses.

### SUMMARY OF THE INVENTION

In light of the above, a vacuum coating apparatus according to claim 1 is provided. Furthermore, a vacuum coating apparatus according to claim 9 is provided. Moreover, a vacuum coating apparatus according to claim 14 is provided. Furthermore, an evaporation unit according to claim 17 is provided. Moreover, a method for coating a web according to claim 20 is provided.

According to one embodiment, a vacuum coating apparatus for coating a web is provided. The apparatus includes a vacuum chamber, a first rotatable coating drum and a second rotatable coating drum disposed parallel to the first drum with a gap formed between the first and the second coating drums for transporting at least one web. A first evaporator includes at least one evaporation source for generating a first evaporation beam, wherein the first evaporator is arranged next to the first coating drum. A second evaporator includes at least one evaporation source for generating a second evaporation beam, wherein the second evaporator is arranged next to the second coating drum. The first and the second evaporators are inclined relative to each other.

According to an embodiment, an evaporation unit is provided. The evaporation unit includes a first evaporator with at least one evaporation source for generating a first evaporation beam and a second evaporator with at least one evaporation source for generating a second evaporation beam. The first and the second evaporators are inclined relative to each other.

According to an embodiment, a method for coating a web is provided. The method includes providing a first rotatable coating drum and a second rotatable coating drum disposed parallel to the first drum with a gap formed between the first and the second coating drums; forming a common evaporation zone next to the surface of the first and second coating drums by evaporating a material from a first evaporator from a first evaporation direction and evaporating a material from a second evaporator from a second evaporation direction; transporting at least one web by the first and/or the second coating drums through the common evaporation zone.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may include other equally effective embodiments.

FIG. 1 illustrates an embodiment of a vacuum coating apparatus having two evaporation sources and two coating drums arranged parallel to each other.

FIG. 2A shows an enlarged section of a vacuum coating apparatus having two evaporation sources for illustrating the arrangement of the evaporation sources relative to the coating drums according to an embodiment.

FIG. 2B shows an enlarged section of a vacuum coating apparatus having two evaporation sources for illustrating the arrangement of the evaporation sources relative to the coating drums according to an embodiment.

FIG. 2C shows an enlarged section of a vacuum coating apparatus having two evaporation sources for illustrating the arrangement of the evaporation sources relative to the coating drums according to an embodiment.

FIG. 3 illustrates an embodiment of a vacuum coating apparatus having one evaporation source and two coating drums arranged parallel to each other.

FIG. 4 illustrates an embodiment of a vacuum coating apparatus having two evaporation sources and one coating drum.

FIG. 5 illustrates an embodiment of a vacuum coating apparatus having one evaporation source and two coating drums arranged parallel to each other.

FIG. 6 illustrates an embodiment of a vacuum coating apparatus having two evaporation sources and two coating drums arranged parallel to each other.

FIG. 7 illustrates a vacuum coating apparatus according to one or more embodiments.

FIG. 8 illustrates an evaporator unit according to one or more embodiments.

FIGS. 9A and 9B illustrate the evaporation beam of an evaporation source.

FIG. 10 illustrates a plan view of two coating drums arranged parallel to each other according to one or more embodiments.

To facilitate understanding, identical or similar reference numerals have been used where possible, to designate identical elements that are common to the figures. It is considered that elements disclosed in one embodiment may be beneficially utilized on other embodiments without specific reference.

### DETAILED DESCRIPTION

Embodiments described herein can be used for a variety of coating processes, such as coating of a web, which is conveyed by at least one coating drum arranged within a vacuum chamber.

In the following Detailed Description, reference is made to the accompanying drawings, which form a part hereof, and in which are shown by way of illustration specific embodiments in which the invention may be practiced. In this regard, directional terminology, such as “top”, “bottom”, “front”, “back”, leading”, “trailing” etc., is used with reference to the orientation of the Figure(s) being described. Because components of embodiments can be positioned in a number of different orientations, the directional terminology is used for purpose of illustration and is in no way limiting. It is to be understood that other embodiments may be utilised and structural or logical changes may be made. The following detailed description, therefore, is not to be taken in a limiting sense. The embodiments being described use specific language, which should not be construed as limiting the scope of the appended claims.

It is to be understood that features of the various exemplary embodiments described herein may be combined with each other, unless specifically noted otherwise. For example, features illustrated or described as part of one embodiment can be used in conjunction with features of other embodiments to yield yet a further embodiment. It is intended that the present description includes such modifications and variations.

For the purpose of this specification, the term “lateral” is intended to describe a direction perpendicular to the orientation of coating drums and substantially parallel to a connection line connecting the axis of rotation of the coating drums. The term “behind the coating drums” is intended to describe a region which is arranged behind the coating drums with respect to the evaporation source. Therefore, the term “before the coating drums” is intended to describe a region which is between the coating drum or drums and the evaporation source.

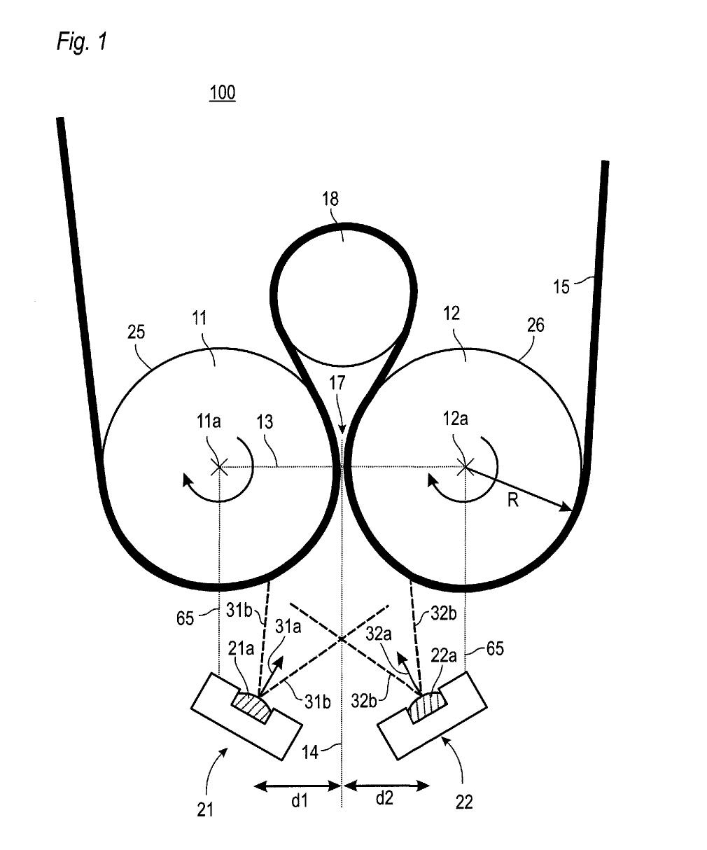

FIG. 1 illustrates a vacuum coating apparatus 100 according to one embodiment, which can be combined with other embodiments described herein. The vacuum coating apparatus 100 includes a first coating drum 11 having an axis of rotation 11a around which the first coating drum 11 is rotatable. FIG. 1 shows the axis 11a as geometrical centre of the first coating drum 11. The vacuum coating apparatus 100 further includes a second coating drum 12 having an axis of rotation 12a around which the second coating drum 12 is rotatable. FIG. 1 shows the axis 12a as geometrical centre of the second coating drum 12. First and second coating drums 11 and 12 are disposed relative to each other so that their axes 11a and 12a are arranged parallel to each other. A gap 17 is formed between outer circumferential surfaces 25 and 26 of the first and second coating drums 11 and 12.

The parallel arrangement of first and second coating drums 11 and 12 increases the available surface on which a web 15 can be coated while in contact with the coating drums as described further below. This allows, for example, utilization of smaller coating drums in comparison to vacuum coating apparatuses using a single large coating drum. When using smaller coating drums the size of the vacuum coating apparatus can be reduced. Furthermore, drives needed for rotating the coating drums can be reduced. In embodiments, which can be combined with one or more embodiments described herein, the web 15 is coated while being supported by, and in contact with portions of, the outer surfaces 25 and 26 of the rotating first and second coating drums 11 and 12.

Gap 17 can be comparably small, for example to maintain a pressure difference between an upper chamber and a lower chamber as described further below. Gap 17 can be in a range from about 1 mm to about 60 mm. Furthermore, the ratio R/D between radius R of the coating drums 11 and 12 and width D of gap 17 can be in a range from about 500 to about 1. For example, ratio R/D can be equal to or larger than 15. According to an embodiment, which can be combined with one or more embodiments described herein, the ratio R/D can be equal to or larger than 100.

In the embodiment illustrated in FIG. 1, both the first and the second coating drums 11 and 12 have the same radius R. In further embodiments, first coating drum 11 can have a larger radius than second coating drum 12. Alternatively, first coating drum 11 can have a smaller radius than second coating drum 12.

The vacuum coating apparatus 100 further includes at least a first evaporator 21 having at least one evaporation source 21a. Typically, vacuum coating apparatus 100 includes a plurality of first evaporators 21 each having an evaporation source 21a. Alternatively, first evaporator 21 includes a plurality of evaporation sources 21a. Irrespective of whether there are individual first evaporators 21 or whether there is only one first evaporator 21 having a plurality of evaporation sources 21a, the evaporation sources 21a can be arranged along a line parallel to the axes of rotation 11a, 12a of the first and second coating drums 11, 12. Evaporation sources 21a are then arranged in a first row parallel to axis 11a. Since FIG. 1 illustrates a projection along the axes 11a, 12a, only one evaporation source 21a is shown. First evaporator 21 is arranged next to the first coating drum 11. The first evaporator 21, particularly the evaporation source 21a of first evaporator 21, is arranged closer to the first coating drum 11 than to the second coating drum 12.

A second evaporator 22 having an evaporation source 22a can be arranged next to the second coating drum 12. The second evaporator 22, particularly the evaporation source 22a of second evaporator 22, is arranged closer to the second coating drum 12 rather than to the first coating drum 11. Second evaporator 22 can have the same arrangement as first evaporator 21. For example, second evaporator 22 can include a plurality of evaporation sources 22a which are arranged in a second row parallel to the axis 12a. First and second rows of evaporation sources 21a, 22a are laterally displaced relative to each other as described below.

First and second evaporators 21 and 22 are configured to generate respective evaporation beams 31b and 32b which can also be referred to as evaporation lobes or emission lobes of the evaporated material. Each of the evaporation beams 31b and 32b has a main evaporation direction 31a and 32a which is typically normal to the surface of the respective evaporation source 21a and 22a from which material evaporates. A skilled person will appreciate that each evaporation source 21a, 22a has a given spatial extension. An evaporation source is therefore defined as an area from which material evaporates. As described above, each of the first and second evaporators 21 and 22 can include at least one evaporation source 21a and 22a. The evaporation sources are separate to, and spaced apart from, each other. For example, an evaporator can include a ceramic crucible or boat adapted to melt a metal. The crucible can be made of a conductive ceramic and heated by directly passing an electrical current therethrough. Inductive heating is another option. A further option is electron beam heating. Evaporation sources are therefore thermal sources where material is evaporated due to heating. The region of the melted metal forms the actual evaporation source. FIG. 1 indicates the evaporation beams 31b, 32b by dashed lines.

The melted metal typically covers or wets a given region of the crucible. The orientation of the surface of the crucible wetted by the melted metal determines the main evaporation direction which is perpendicular thereto. Hence, by arranging the crucible in a given orientation, the main direction of evaporation can be changed.

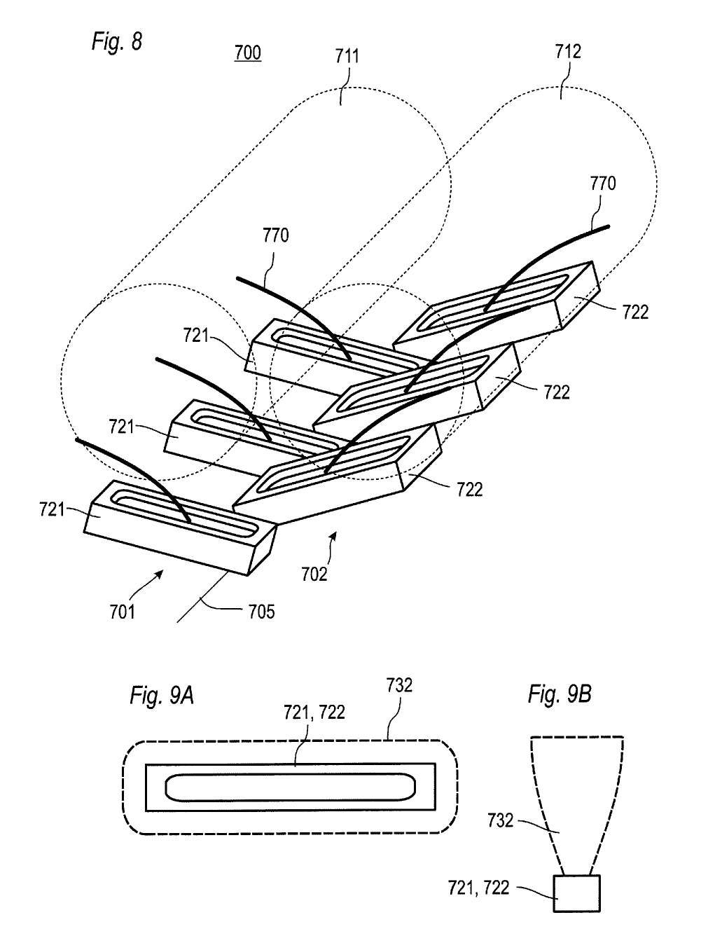

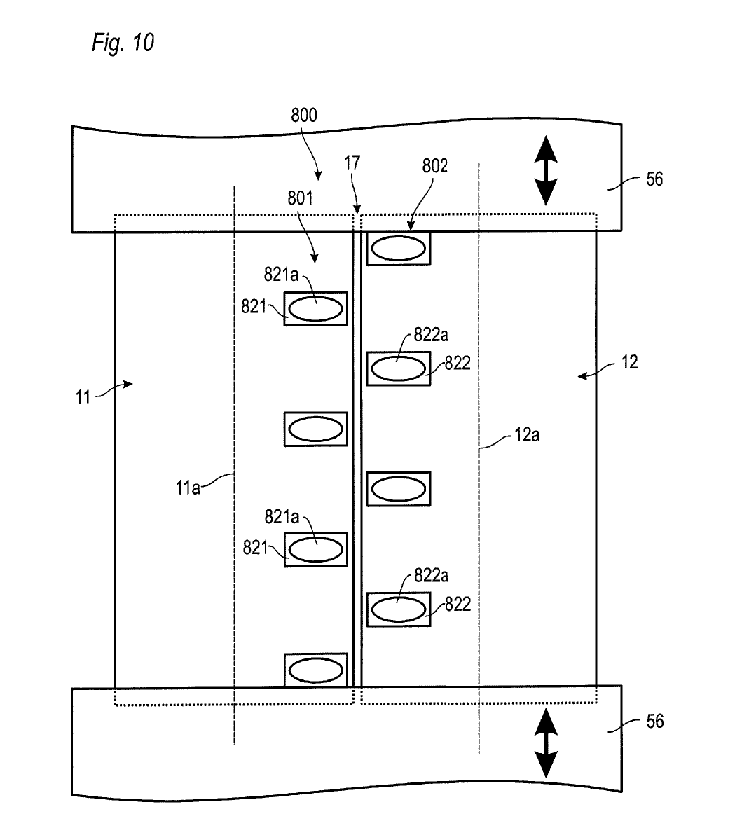

According to an embodiment which can be combined with one or more embodiments described herein, first and second evaporators 21 and 22 can be arranged in a staggered manner when seen in a projection normal to the first and second axes 11a and 12a. FIGS. 8 and 10 illustrate this by showing a plurality of first evaporators 21 each having an evaporation source 21a and a plurality of second evaporators 22 each having a plurality of evaporation sources. In further embodiments, which can be combined with one or more embodiments described herein, first and second evaporators 21 and 22 can be combined into a single evaporator unit having two rows of evaporation sources with the rows being spaced apart from each other.

A skilled person will appreciate that the distribution of evaporated material is not uniform within the evaporation beams 31b and 32b and decreases from the centre of the evaporation beams towards their boundary illustrated here by dashed lines 31b and 32b. Moreover, the evaporation beams 31b and 32b will have a given opening angle. The evaporation beams typically do not have sharp boundaries due to the spatial distribution of the evaporated material. For illustration purposes only and not meant to be limiting in any way, an A1 evaporation source is considered which is spaced from a surface by about 180 mm. The evaporation source has a lateral size of about 30 mm. The evaporation source generates an evaporation beam at a given temperature which results in a deposited A1 layer area on the surface which has a lateral extension of about 80-100 mm wherein the layer thickness at the edge of the deposited layer is only about 10% of the layer thickness in the centre of the deposited layer area.

As illustrated in FIG. 1, evaporation beam 31b of first evaporator 21 is inclined with respect to the surface of the first drum 11 The main evaporation direction 31a of evaporation beam 31b is inclined with respect to an imaginary line between the evaporation source 21a of the first evaporator 21 and the axis 11a of the first coating drum 11 when seen in a projection along axis 11a. Furthermore, evaporation beam 32b of the second evaporator 22 is inclined with respect to the surface of the second drum 12. The main evaporation direction 32a of evaporation beam 32b is inclined with respect to an imaginary line between the evaporation source 22a of the second evaporator 22 and the axis 12a of the second coating drum 12 when seen in a projection along axis 12a. The main evaporation directions 31a and 32a of the evaporation beams 31b and 32b therefore do not strike the outer surfaces 25 and, 26 of the respective closest coating drums 11 and 12, which are perpendicular but at a specific incident angle.

The evaporation beams 31b and 32b can furthermore be inclined relative to each other. As described above, the orientation of the evaporation beams 31b and 32b can be defined by the orientation of the evaporation sources 21a and 22a. To incline the evaporation beams 31b and 32b relative to each other, the evaporation sources 21a and 22a are inclined relative to each other. FIG. 1 illustrates that the evaporation sources 21a and 22a are inclined relative to each other so that the evaporation beams 31b and 32b are inclined towards each other and overlap each other when seen in a projection along axis 11a and 12a. A common deposition zone or common evaporation cloud is thus formed.

As described above, first and second evaporation sources 21a and 22a can be displaced in a direction parallel to the axes 11a and 12a. For example, a plurality of evaporation sources 21a and 22a can be arranged in a staggered manner. The term “inclined towards each other” therefore relates to the orientation when seen in a projection along axis 11a and 12a.

First and second coating drums 11 and 12 transport a web 15 to be coated through the deposition zone along their circumferential surfaces 25 and 26. As illustrated in FIG. 1, web 15 is transported around a lower half of second coating drum 12, passing through gap 17 to be guided back through gap 17 by a guide roller 18, and then transported along the lower half of first coating drum 11. First and second coating drums 11 and 12 form together a large coating area where web 15 can be coated. Due to the use of guide roller 18, web 15 is “double” coated with the first coating, occurring when transported by second coating drum 12, with the second coating occurring when transported by first coating drum 11. First and second coating drums 11 and 12 have the same rotational direction.

First and second coating drums 11 and 12 as well as guide roller 18 can be cooled. It would also be possible to cool only guide roller 18. Alternatively, only first and second coating drums 11 and 12 can be cooled.

The inclined arrangement of the evaporators 21 and 22 avoids, or at least significantly reduces deposition of material in outer regions laterally outer to first and second coating drums 11 and 12. These outer regions are arranged on sides of the first and second coating drums 11 and 12 opposite to sides facing gap 17. The inclined arrangement therefore increases the ratio of the material deposited onto web 15 to the material deposited on other surfaces within the coating apparatus such as shielding means. Hence, the coating process is more efficient which increases the yield and reduces productions cost. This also allows increasing the conveying speed of the web 15 since more material can be deposited in a given time.

For example, coating efficiency of up to 90% and even more is obtainable using the inclined arrangement of first and second evaporators 21 and 22. This is a significant improvement over commonly used evaporator units having a plurality of evaporator sources directing into the same direction which have a coating efficiency of not more than 60%.

The reduced deposition of material onto shielding means is useful for many reasons. Shielding means are typically used to restrict the deposition within desired areas and to protect other areas from deposition. For example, lateral shielding means can be provided to “shape” deposition zone. The inclined arrangement as described herein can be used to shape or focus the deposition zone so that in some applications no additional shielding means are needed to constrain the deposition zone. Shielding means, however, can be optionally used, for example when deposition of material from regions “outside” to the evaporation beams 31b and 32b should be avoided. Although the evaporation beams 31b and 32b are illustrated to cover a certain region only, a skilled person will appreciate that material is also evaporated to regions outside of the evaporation beams although only to a small degree. However, this small amount may deteriorate the coated layer when becoming deposited. For example, webs are often coated with aluminium to obtain a reflective surface. Material deposited from “outside” of the technically useful evaporation beams can reduce the reflectivity. To avoid this, shielding means can be provided.

Reducing deposition of evaporated material on shielding means furthermore facilitates cleaning of the vacuum coating apparatus since cleaning does not have to be carried out at high frequency.

For example, evaporation sources 21a and 22a of first and second evaporators 21 and 22 can be arranged within vertical lines 65 which are perpendicular to an imaginary connection line 13 and which pass through the respective axis 11a and 12a of the first and second coating drums 11 and 12. Imaginary line 13 connects axis of rotation 11a of first coating drum 11 with axis of rotation 12a of second coating drum 12. In other words, the evaporation sources 21a and 22a are spaced relative to each other by a distance L which can be less than 2*R+D, typically less than 2*R as the width D of gap 17 is typically much smaller than radius R. In one embodiment, which can be combined with one or more embodiments described herein, L is equal to or less than radius R. Distance L can be, for example, between 150 mm and 200 mm.

When placing the evaporation sources 21a and 22a at a comparatively small distance from each other, for example at a distance less than 2*R, the respective “outer” boundaries of the evaporation beams 31b and 32b are shifted inwards so that they are more remote from the lateral outer edge of the respective coating drums 11 and 12 when seen in a projection along the axis 11a and 12a. This focuses the deposition towards the centre between the coating drums 11 and 12 away from the lateral outer regions and thus reduces the likelihood that material is deposited laterally outside of the coating drums 11 and 12.

This effect is even more pronounced when inclining the evaporators 21 and 22 towards each other as described above. The respective outer edges of the evaporators 21 and 22 can even be tilted towards the common centre of the first and second coating drums 11 and 12.

First and second evaporators 21 and 22 can be laterally arranged in spaced relation to a vertical line 14 constructed perpendicular to the imaginary connection line 13. Vertical line 14 runs through gap 17. The respective lateral displacement by distances d1 and d2 can be selected according to specific needs. Distances d1 and d2 can be identical. Alternatively, distances d1 and d2 can be different to each other. For example, when first and second coating drums 11 and 12 have the same radius R, d1 is typically substantially equal to d2. When using coating drums of different radii, d1 can be different to d2.

Web 15 can be any suitable band-shaped flexible material. Typical examples are foils. Coated foils can be used as food packaging material. The evaporated material can be any material which can be suitably evaporated such as metals or dielectric materials. An example is aluminium. Another example is copper. The material can be delivered as wire which is melted in the heated evaporator.

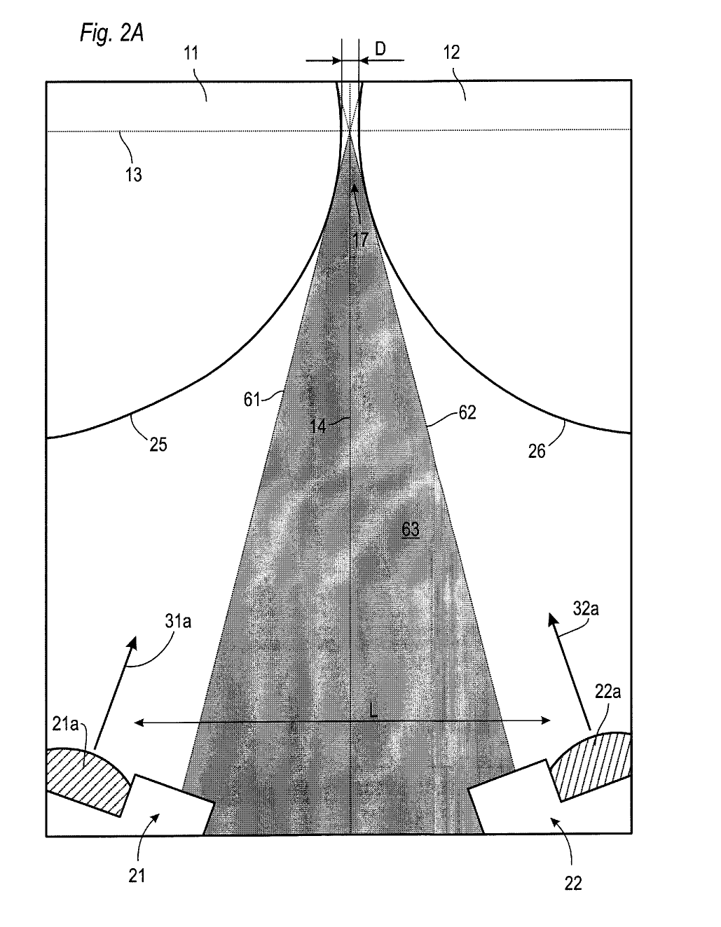

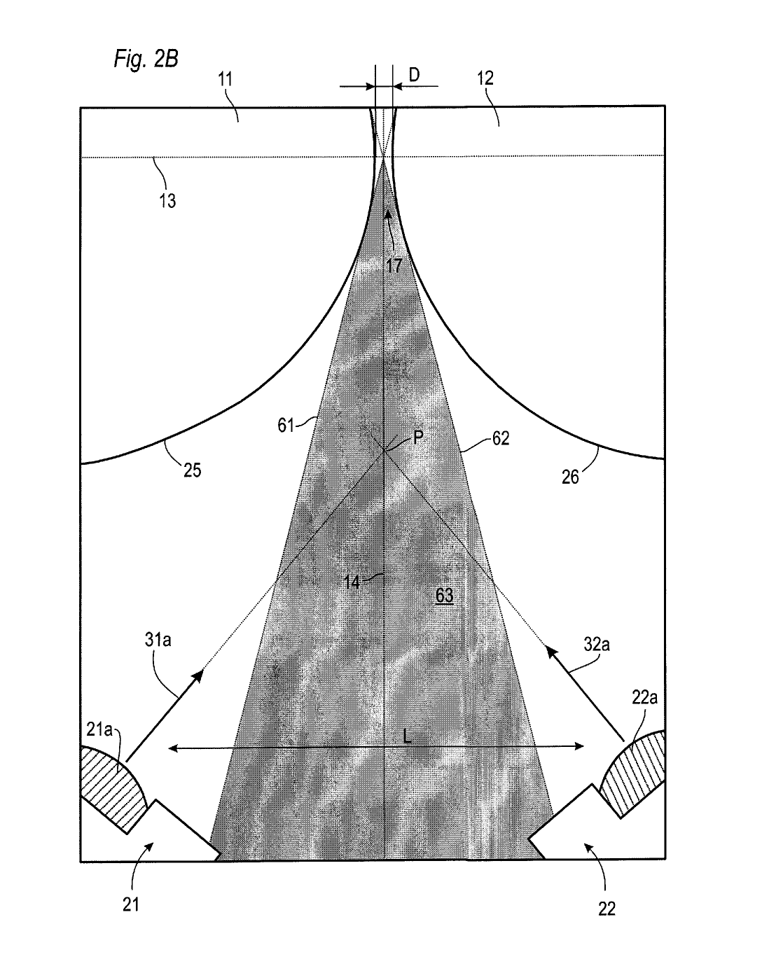

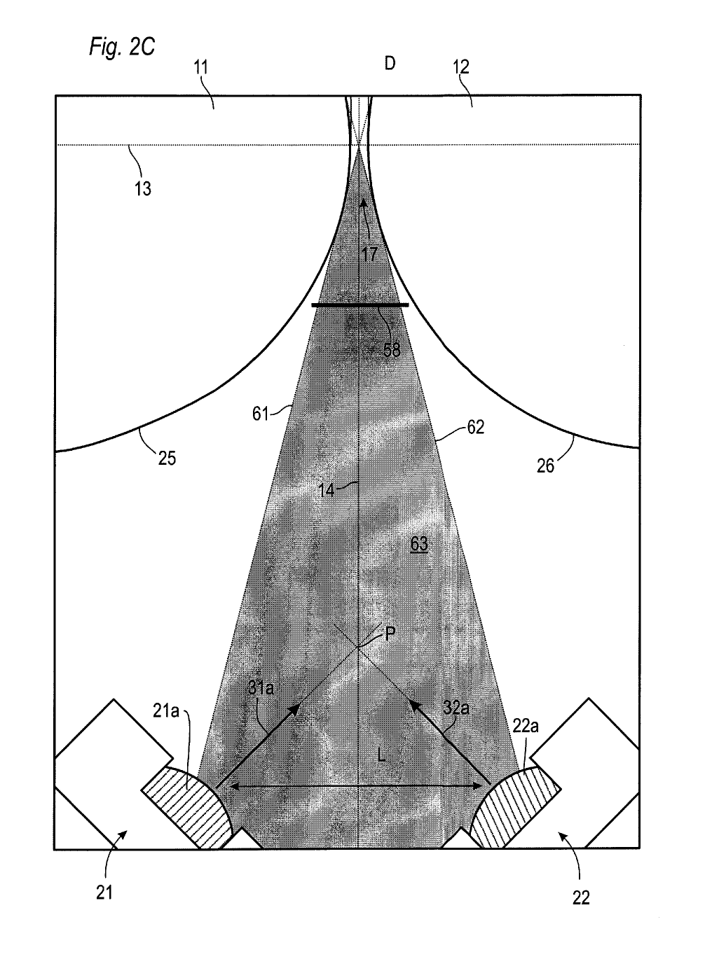

According to embodiments, which can be combined with one or more embodiments described herein, evaporators 21 and 22 are arranged such that no evaporated material can pass through the gap 17 along a straight line from the respective evaporation source 21a and 22a. This is illustrated in FIG. 2A showing an enlarged detail of FIG. 1. Evaporation sources 21a and 22a of the first and second evaporators 21 and 22 are directed towards the coating drums 11 and 12 in an inclined manner with respect to each other and also with respect to line 14 running through gap 17. The term “directed towards” intends to describe that the main evaporation direction of the respective evaporation source points in the indicated direction.

The evaporation sources 21a and 22a are arranged outside of an area 63 which can be constructed by lines 61 and 62, passing through the gap 17 and being common tangents of the first and second coating drums 11 and 12. Each line 61 and 62 forms a tangent both of the first and the second coating drums 11 and 12. These lines 61 and 62 constrain area 63 which is centred on line 14. Area 63 is illustrated in gray. Material which is evaporated outside area 63 cannot directly pass through gap 17 along a straight line. First and second coating drums 11 and 12 form a shielding for gap 17 to prevent evaporated material from passing through gap 17. The deposition zone is therefore substantially restricted to a region lying “before” gap 17.

When arranging the evaporation sources 21a and 22a as described above, no shielding means are needed, neither before nor behind the gap 17. This furthermore improves the yield since no material deposits onto a shielding means which would need to be cleaned at regular intervals.

As illustrated in FIG. 2A, evaporation sources 21a and 22a are arranged such that the geometrical extension of the main evaporation direction 31a and 32a intersects at a point P (not illustrated here) which is arranged behind gap 17. By doing so, the evaporated material is more evenly distributed within the deposition zone and not focussed on a single region. On the other hand, since the evaporation beams 31b and 32b are inclined towards each other, the concentration of the evaporated material within the evaporation zone is increased which allows disposing the evaporations sources 21a and 22a at a greater distance, for example to reduce thermal stress of the web 15. Furthermore, the conveying speed of the web 15 can be increased.

FIG. 2B illustrates another embodiment which can be combined with one or more embodiments described herein. The arrangement of the first and second evaporators 21 and 22 is similar to that shown in FIG. 2A except that the first and second evaporators 21 and 22 are more inclined towards each other so that point P of the geometrical intersection of the main evaporation directions 31a and 32a is arranged before gap 17. This increases the concentration of evaporated material even further, which also allows the distance between the evaporation sources 21 and 22a and the surface of the first and second coating drums 11 and 12 to increase.

The evaporation beams 31b and 32b “cross” each other in this embodiment, when seen in a projection normal to the axis 11a and 12a, before reaching the surface 25 and 26 of the coating drums 11 and 12. Particularly, first evaporator 21 arranged next to the first coating drum 11 is directed towards the second coating drum 12 while second evaporator 22 arranged next to the second coating drum 12 is directed towards the first coating drum 11 so that a “cross-deposition” occurs.

Evaporated material from first evaporation source 21a “passes” outer surface 25 of first coating drum 11 Deposition on first coating drum 11 by first evaporation source 21a also occurs. Material is deposited at an inclined angle with respect to the normal of the surface 25 of the first coating drum 11. In a similar manner deposition from second evaporation source 22a on second coating drum 12 occurs. Hence, web 15, when on surface 25 of first coating drum 11, is coated by evaporation sources 21a and 22a of both the first and second evaporation sources 21 and 22. Similar, web 15, when on surface 26 of second coating drum 12, is coated by evaporation sources 21a and 22a of both the first and second evaporation sources 21 and 22.

The ratio of deposition onto first and second coating drums 11 and 12 with respect to one evaporation source can be adjusted by the angle of inclination with respect to the normal of the drum surfaces 25 and 26 and the distance to the coating drums 11 and 12.

According to an embodiment which can be combined with one or more embodiments described herein, deposition from first evaporator 21 onto the second coating drum 12 can occur under an angle which is larger than an angle under which the deposition from first evaporator 21 onto the first coating drum 11 occurs. The angle is defined with respect to the surface of the coating drum under which the main evaporation direction strikes the respective surface. Accordingly, deposition from second evaporator 22 onto the first coating drum 11 can occur under an angle which is larger than an angle under which deposition from second evaporator 22 onto the second coating drum 12 occurs.

It is, however, also possible to arrange first and second evaporators 21 and 22 within area 63. Although a “straight” path is formed between the evaporation sources 21a, 22a and gap 17, deposition through gap 17 can be significantly reduced by inclining the evaporation sources 21a and 22a towards each other so that the main direction of evaporation 31a and 32a of the respective evaporation sources 21a and 22a points towards the respective opposite coating drum. If needed, a shielding 58 can be provided to cover gap 17.

An evaporation source which is arranged next to a neighbouring coating drum is directed towards another coating drum which is arranged a greater distance from that evaporation source than the neighbouring coating drum as illustrated in FIGS. 2B and 2C. In FIG. 2A, the evaporation source is directed towards its neighbouring coating drum and partially inclined towards the other coating drum arranged distal to the evaporation source.

The inclination angle between the evaporation sources 21a and 22a (defined by the angle between the main evaporation directions 31a and 32a) can be selected according to specific needs and can be, for example, between about 60° and about 180°.

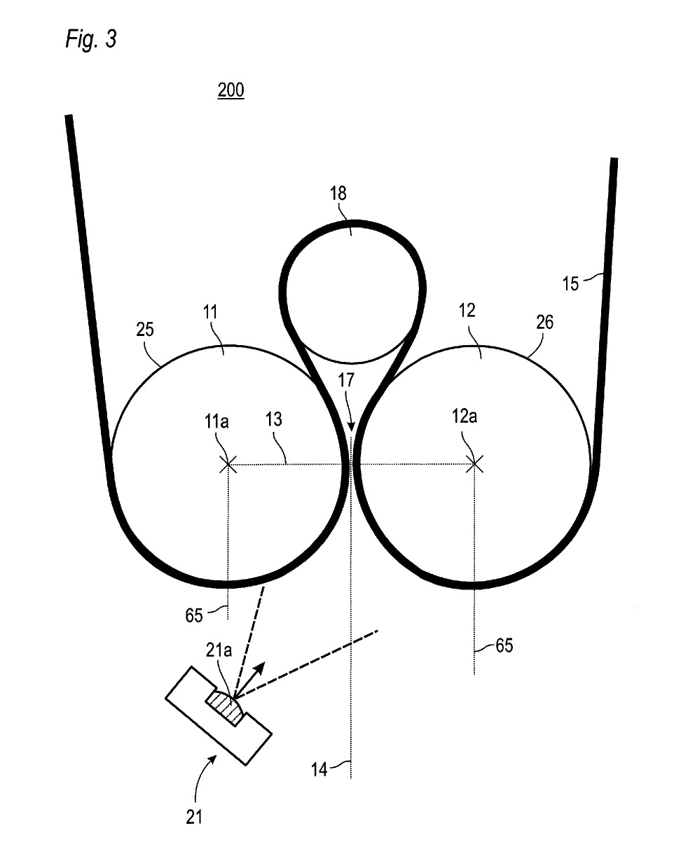

According to an embodiment, which can be combined with one or more embodiments described herein, a vacuum coating apparatus 200 can include a first evaporator 21 only as illustrated in FIG. 3. First evaporator 21 can be arranged similarly as described in connection with FIG. 1 and any of the FIGS. 2A to 2C. First evaporator 21 can have a position and placement relative to the first and second coating drums 11 and 12 as described in connection with any of the FIGS. 2A to 2C.

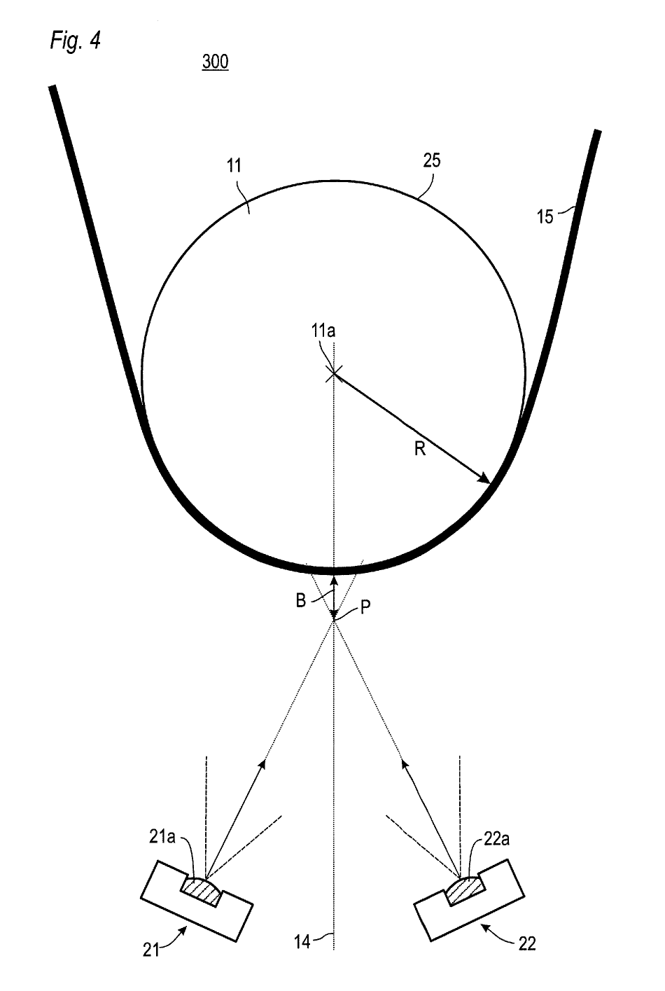

FIG. 4 illustrates a further embodiment, which can be combined with one or more embodiments described herein. Vacuum coating apparatus 300 includes only one coating drum 11. First and second evaporators 21 and 22 can be arranged as described above. The geometrical extension of main evaporation directions 31a and 32a of the first and second evaporators 21 and 22 intersects at a point P before reaching surface 25 of the coating drum 11 and web 15 transported by coating drum 11, respectively. Point P is then spaced from the outer surface 25 of coating drum 11 by a distance B. Alternatively, point P can be close to or on the outer surface 25 of coating drum 11. In a further alternative, point P can lie between the outer surface 25 of the coating drum 11 and its axis of rotation 11a.

When point P is spaced from the outer surface of coating drum 11, B can be between 0 mm and 100 mm. Alternatively, when point P is “within” the coating drum 11, B can be in a range from about 0 (at the surface) to about −R (at the centre of the coating drum) with R being the radius of the coating drum 11.

As described above, inclining the evaporation sources 21a and 22a towards each other results in a more focussed deposition zone having a more uniform distribution of evaporated material than using a single source or when using two evaporation sources which point in the same direction, i.e. which are parallel to each other. Furthermore, the evaporation beams strike the circumferential surface 25 of the coating drum 11, and therefore the surface of web 15, under an inclined angle and not normal to the surface. This also improves the deposition process.

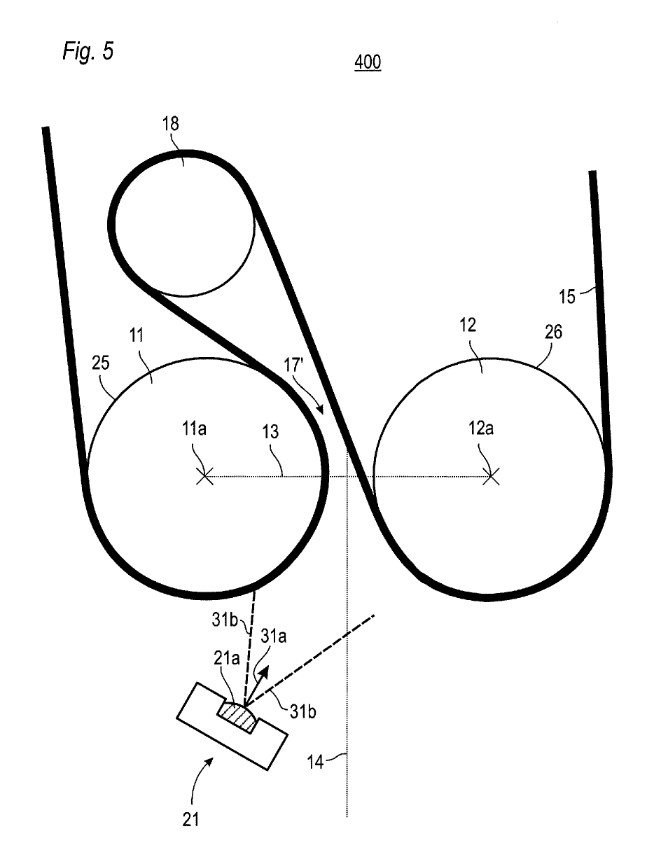

FIG. 5 illustrates a further embodiment of a vacuum coating apparatus 400, which can be combined with one or more embodiments described herein. The vacuum coating apparatus 400 includes two coating drums 11, 12 arranged parallel to each other by a gap 17′ which is larger than the gap 17 of FIG. 1. Guide roller 18 is laterally displaced with respect to perpendicular line 14 passing through the middle between first and second coating drums 11 and 12. Lateral displacement of guide roller 18 ensures that evaporated material passing through gap 17′ deposits onto web 15.

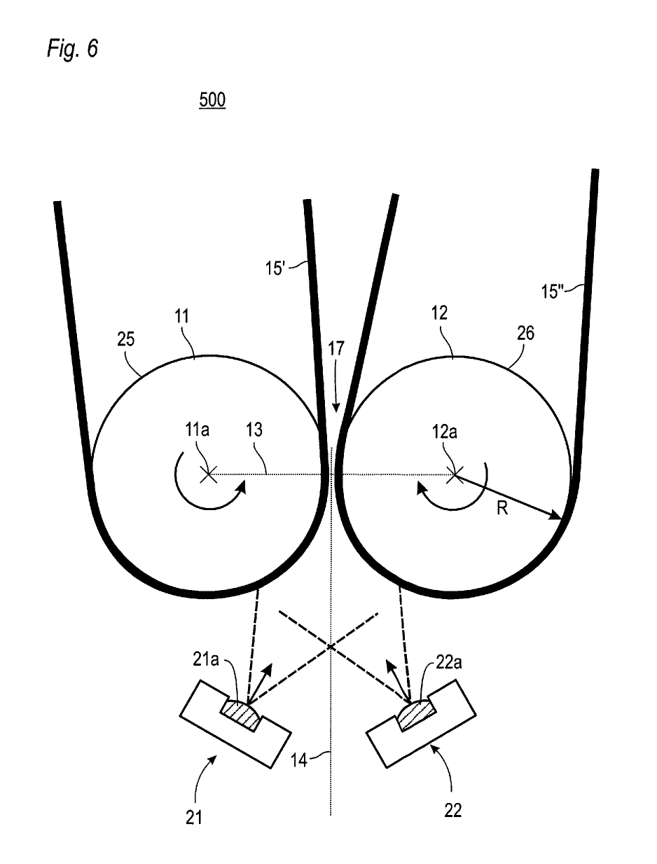

FIG. 6 illustrates a further embodiment of a vacuum coating apparatus 500, which can be combined with one or more embodiments described herein. The vacuum coating apparatus 500 includes two coating drums 11 and 12 arranged parallel to each other with a gap 17 formed in between. In contrast to FIG. 1, two webs are coated at the same time with web 15′ being conveyed by first coating drum 11 while web 15″ is conveyed by second coating drum 12. Coating drums 11 and 12 can have the same rotational direction. Alternatively, coating drums 11 and 12 can have opposite rotational directions.

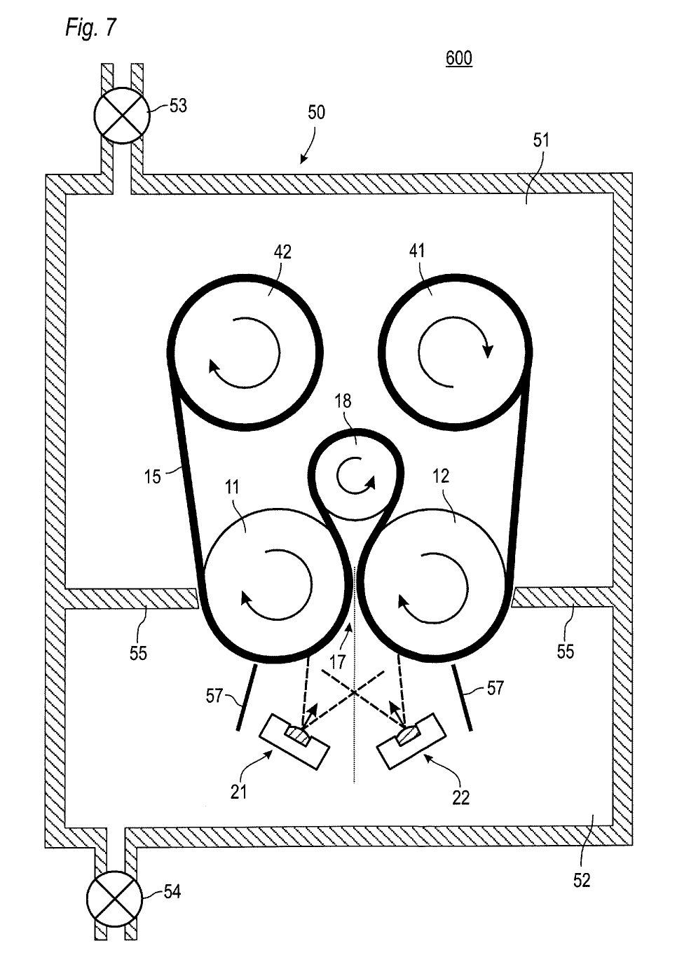

FIG. 7 illustrates a further embodiment of a vacuum coating apparatus 600, which can be combined with one or more embodiments described herein. The vacuum coating apparatus 600 includes two coating drums 11 and 12 arranged parallel to each other with a gap 17 formed between the two coating drums 11 and 12. The vacuum coating apparatus 600 includes a housing 50 having an upper chamber 51 and a lower chamber 52. An unwinding drum 41 and a winding drum 42 are arranged in upper chamber 51. Guide roller 18 is also arranged in upper chamber 51. First and second coating drums 11 and 12 are partially arranged in upper chamber 51 while a lower portion of both, for example a lower half, projects into the lower chamber 52 which forms the deposition chamber in which evaporation sources 21 and 22 are arranged. Shielding means 57 can be arranged lateral to the evaporation sources 21 and 22, to avoid that traces of evaporated material can deposit onto the transported web 15.

First upper chamber 51 can be evacuated through valve 53 while lower chamber 52 can be evacuated through valve 54. Typically, there is a pressure difference between upper and lower chambers 51 and 52. For maintaining the pressure difference, wall portions 55 reach close to the outer surface of the coating drums to leave only a small clearance. Gap 17 can also be made comparatively small to maintain the vacuum pressure difference between upper chamber 51 and lower chamber 52.

FIG. 8 illustrates an embodiment of an evaporator unit 700, which can be combined with one or more embodiments described herein. Evaporation unit 700 includes two evaporation rows 701, 701. Each row 701, 702 includes a plurality of evaporators 721, 722 which are laterally spaced two each other at a substantially constant distance within each row 701 and 702 along a line 705 which is arranged perpendicular to the moving direction of the web 15. Web 15 is not illustrated here. First and second coating drums 711 and 712 are illustrated in phantom lines.

Evaporator unit 700 can include, for example, 25 to 30 evaporators 721 and 722 arranged in two rows 701 and 702.

The rows 701 and 702 are displaced relative to each other along line 705 to obtain a staggered arrangement of the individual evaporators 721 and 722. Furthermore, evaporators 721 and 722 of the respective rows 701 and 702 can partially overlap each other when seen along line 705 which is parallel to the axes of rotation of the coating drums.

As illustrated in FIG. 8, evaporators 721 of row 701 and evaporators 721 of row 702 are inclined relative to each other as described further above to form a common evaporation zone.

Evaporators 721 and 722 are formed here by heated crucibles to melt metal delivered as wire 770. Each crucible has an elongated shape to form a respective evaporation beam 732. FIGS. 9A and 9B illustrate the evaporation beams 732 of the respective evaporators 721 and 722 used in FIG. 8.

The crucibles forming the evaporators 721 and 722 are inclined with respect to each other. Each crucible is delivered with a metal wire 770 to melt the metal. Delivery rate of the wire 770 can be adjusted such that the melting rate is similar to the evaporation rate. Excess of melted metal can be reduced to avoid the melted metal flowing off the inclined crucibles. For example, the delivery rate of melted metal can be adjusted such that the surface of the crucibles is only wetted by a thin liquid metal film. Each crucible 721 and 722 can be, for example, 30 mm wide and 180 mm long.

FIG. 10 illustrates an embodiment of an evaporator unit 800, which can be combined with one or more embodiments described herein. Evaporation unit 800 includes a first row 801 of evaporators 821 and a second row 802 of evaporators 822, each of which includes a respective evaporation source 821a and 822a, respectively. Different to the evaporation unit 700 of FIG. 8, evaporators 821 and 822 of the respective rows 802 and 802 do not overlap each other in a projection parallel to the axes 11a and 12a of the coating drums 11 and 12.

FIG. 10 further illustrates movable shielding means 56 covering respective ends of coating drums 11 and 12. Shielding means 56 are used to restrict deposition and to adapt the deposition zone when band material of a different size is used.

According to an embodiment, which can be combined with one or more embodiments described herein, a vacuum coating apparatus for coating a web is provided. The apparatus includes a vacuum chamber, a first rotatable coating drum and a second rotatable coating drum disposed parallel to the first drum with a gap formed between the first and the second coating drums for transporting at least one web. A first evaporator includes at least one evaporation source adapted to generate a first evaporation beam, wherein the first evaporator is arranged next to the first coating drum. A second evaporator includes at least one evaporation source adapted to generate a second evaporation beam, wherein the second evaporator is arranged next to the second coating drum. The first and the second evaporators are arranged such that their evaporation beams are inclined relative to each other.

According to an embodiment, which can be combined with one or more embodiments described herein, a vacuum coating apparatus for coating a web is provided. The apparatus includes a vacuum chamber, a first rotatable coating drum and a second rotatable coating drum disposed parallel to the first drum with a gap formed between the first and the second coating drums for transporting at least one web. A first evaporator includes at least one evaporation source arranged next to the first coating drum. A second evaporator includes at least one evaporation source arranged next to the second coating drum. The first and the second evaporators are inclined relative to each other.

According to an embodiment, which can be combined with one or more embodiments described herein, each of the evaporation beams of the first and second evaporators includes a main evaporation direction, wherein the geometrical extensions of the respective main evaporation directions intersect at a point P arranged before the gap.

According to an embodiment, which can be combined with one or more embodiments described herein, each of the evaporation beams of the first and second evaporators includes a main evaporation direction, wherein the geometrical extensions of the respective main evaporation directions intersect at a point P arranged behind the gap.

According to an embodiment, which can be combined with one or more embodiments described herein, each of the evaporation beams of the first and second evaporators includes a main evaporation direction, wherein the geometrical extensions of the respective main evaporation directions intersect at a point P arranged within the gap.

According to an embodiment, which can be combined with one or more embodiments described herein, the first and second coating drums are configured for transporting a web through the gap, wherein the first and the second evaporators are arranged relative to the first and second coating drums such that the gap is hidden from view by a respective one of the first and second coating drums when seen from the evaporation sources of the respective evaporators.

According to an embodiment, which can be combined with one or more embodiments described herein, each of the first and the second coating drums has a radius R, and the gap between the first and second coating drums has a width D when measured along an imaginary connection line connecting the axis of rotation of the first coating drum with the axis of rotation of the second coating drum, wherein the ratio R/D is equal to or larger than 15, particularly larger than 100.

According to an embodiment, which can be combined with one or more embodiments described herein, the vacuum coating apparatus further includes a guide roller arranged behind the first and second coating drums relative to the first and second evaporators for guiding the web through the gap.

According to an embodiment, which can be combined with one or more embodiments described herein, wherein the first and second evaporation beams form a common deposition zone arranged between the first and second evaporators and the first and second coating drums.

According to an embodiment, which can be combined with one or more embodiments described herein, the common deposition zone has a more uniform distribution of evaporated material than a deposition zone formed by a single evaporator when seen in a projection along the axes of the first and second coating drums.

According to an embodiment, which can be combined with one or more embodiments described herein, wherein the vacuum coating apparatus is configured to convey a first web by the first coating drum through the gap and at the same time a second web by the second coating drum through the gap.

According to an embodiment, which can be combined with one or more embodiments described herein, a vacuum coating apparatus for coating a web is provided. The apparatus includes a vacuum chamber, a first rotatable coating drum and a second rotatable coating drum disposed parallel to the first drum with a gap formed between the first and the second coating drums for transporting a web through the gap. At least a first evaporator having an evaporation source is arranged next to the first coating drum and inclined towards the second coating drums for depositing a material onto the web when transported by the second coating drum through the gap. The evaporation source of the first evaporator is arranged closer to the first coating drum than to the second coating drum and disposed relative to the first and second coating drums such that the gap is hidden from view by the first coating drum when seen from the evaporation source of the first evaporator.

According to an embodiment, which can be combined with one or more embodiments described herein, the vacuum coating apparatus further includes at least a second evaporator having an evaporation source inclined towards the first coating drum for depositing a material onto the web when transported by the first coating drum, wherein the second evaporator is arranged closer to the second coating drum than to the first coating drum and is disposed relative to the first and second coating drums such that the gap is hidden from view by the second coating drum when seen from the evaporation source of the second evaporator.

According to an embodiment, which can be combined with one or more embodiments described herein, the first evaporator has a first main evaporation direction and the second evaporator has a second main evaporation direction. The first main evaporation direction and the second main evaporation direction intersect at a point P arranged behind the gap formed between the first and second coating drums.

According to an embodiment, which can be combined with one or more embodiments described herein, the first evaporator has a first main evaporation direction and the second evaporator has a second main evaporation direction. The first main evaporation direction and the second main evaporation direction intersect at a point P arranged before the gap formed between the first and second coating drums.

According to an embodiment, which can be combined with one or more embodiments described herein, each of the first and the second coating drums comprises a radius R. The evaporation source of the first evaporator is spaced from the evaporation source of the second evaporator by a distance L which is less than the radius R of the coating drums.

According to an embodiment, which can be combined with one or more embodiments described herein, the radius R of the first and second coating drums is larger than the distance between the first coating drum and the evaporation source of the second evaporator and/or larger than the distance between the second coating drum and the evaporation source of the first evaporator.

According to an embodiment, which can be combined with one or more embodiments described herein, a vacuum coating apparatus for coating a web is provided. The vacuum coating apparatus includes a vacuum chamber; at least one rotatable coating drum having an axis of rotation and a surface for transporting a web; a first evaporator having at least one evaporation source; a second evaporator having at least one evaporation source. The first and second evaporators are arranged next to the coating drum and are inclined relative to each other.

According to an embodiment, which can be combined with one or more embodiments described herein, the evaporation source of the first evaporator is adapted for generating a first evaporation beam having a first main evaporation direction and the evaporation source of the second evaporator is adapted for generating a second evaporation beam having a second main evaporation directions. The first and the second evaporators are arranged such that their evaporation beams are inclined towards each other.

According to an embodiment, which can be combined with one or more embodiments described herein, the first and the second evaporators are arranged such that the first main evaporation direction and the second main evaporation direction intersect at a point P arranged between the coating drum and the first and second evaporators when seen in a projection parallel to the axis of rotation.

According to an embodiment, which can be combined with one or more embodiments described herein, an evaporation unit or an evaporation arrangement is provided, having a first evaporator with at least one evaporation source for generating a first evaporation beam (31a); and a second evaporator with at least one evaporation source for generating a second evaporation beam, wherein the first and the second evaporators are inclined relative to each other.

According to an embodiment, which can be combined with one or more embodiments described herein, the evaporation unit or evaporation arrangement further includes a first row of first evaporators, wherein each first evaporator is adapted to generate a first evaporation beam; and a second row of second evaporators, wherein each second evaporator is adapted to generate a second evaporation beam. The first and second rows are arranged parallel to each other, wherein the first evaporators of the first row and the second evaporators of the second row are arranged such that the evaporation beams of the first evaporators are inclined towards the evaporation beams of the second evaporators when seen in a projection along the first and second rows.

According to an embodiment, which can be combined with one or more embodiments described herein, the first and second evaporators are arranged in a staggered manner.

According to an embodiment, which can be combined with one or more embodiments described herein, a vacuum coating apparatus is provided. The vacuum coating apparatus includes a vacuum chamber; a first coating drum having an axis and a second coating drum having an axis disposed parallel to the first drum with a gap formed between the first and the second coating drums; at least a first evaporator having an evaporation source which is directed toward the second coating drum for depositing a material onto the web when transported by the second coating drum through the gap. The evaporation source of the first evaporator is arranged outside of an area defined between first imaginary lines which run through the gap and are tangents of both the first and second coating drums when seen in a projection parallel to the axes.

According to an embodiment, which can be combined with one or more embodiments described herein, the vacuum coating apparatus further includes at least a second evaporator with an evaporation source directed toward the first coating drum for depositing a material onto the web when transported by the first coating drum. The evaporation source of the second evaporator is arranged outside of the area defined between the first imaginary lines when seen in a projection parallel to the axes.

According to an embodiment, which can be combined with one or more embodiments described herein, the axes are disposed relative to each other along an imaginary connection line passing through the gap. The evaporation source of the first and/or the second evaporator is/are arranged within an area defined between second imaginary lines which run through a respective one of the axes of the first and second coating drums and which are perpendicular to the imaginary connection line.

According to an embodiment, which can be combined with one or more embodiments described herein, a vacuum coating apparatus for coating a web is provided. The vacuum coating apparatus includes a vacuum chamber; a first rotatable coating drum; and a second rotatable coating drum disposed parallel to the first drum with a gap formed between the first and the second coating drums for transporting a web through the gap. The axes are disposed relative to each other along an imaginary connection line passing through the gap. At least a first evaporator with an evaporation source is directed toward the second coating drums for depositing a material onto the web when transported by the second coating drum through the gap. The first evaporator is arranged relative to the first and second coating drums such that a straight line from the evaporation source through the gap is obstructed by the first coating drum.

According to an embodiment, which can be combined with one or more embodiments described herein, a method for coating a web is provided. The method includes providing a first rotatable coating drum and a second rotatable coating drum disposed parallel to the first drum with a gap formed between the first and the second coating drums; forming a common evaporation zone next to the surface of the first and second coating drums by evaporating a material from a first evaporator from a first evaporation direction and evaporating a material from a second evaporator from a second evaporation direction; transporting at least one web by the first and/or the second coating drums through the common evaporation zone.

While the foregoing is directed to embodiments of the present invention, other and further embodiments of the invention may be devised without departing from the basic scope thereof, and the scope thereof is determined by the claims that follow.

1. A vacuum coating apparatus for coating a web, comprising:
a vacuum chamber;
a first rotatable coating drum having an axis of rotation around which the first coating drum is rotatable and a second rotatable coating drum having an axis of rotation around which the second coating drum is rotatable, the second coating drum being disposed parallel to the first drum with a gap formed between the first and the second coating drums for transporting at least one web;
a first evaporator comprising at least one evaporation source for generating a first evaporation beam, the first evaporator being arranged next to the first coating drum;
a second evaporator comprising at least one evaporation source for generating a second evaporation beam, the second evaporator being arranged next to the second coating drum; and
the first and the second evaporators being inclined relative to each other when seen in a projection along the axis of the first and second coating drums.

2. The vacuum coating apparatus of claim 1, wherein each of the first and second evaporators comprises a main evaporation direction, wherein the geometrical extensions of the respective main evaporation directions intersect at a point arranged before the gap.

3. The vacuum coating apparatus of claim 1, wherein the first and second coating drums are configured for transporting a web through the gap, and wherein the first and the second evaporators are arranged relative to the first and second coating drums such that the gap is hidden from view by a respective one of the first and second coating drums when seen from the evaporation sources of the respective evaporators.

4. The vacuum coating apparatus of claim 1, wherein each of the first and the second coating drums has a radius, and the gap between the first and second coating drums has a width when measured along an imaginary connection line connecting the axis of rotation of the first coating drum with the axis of rotation of the second coating drum, wherein the ratio radius/width is equal to or larger than 15.

5. The vacuum coating apparatus of claim 1, further comprising a guide roller arranged behind the first and second coating drums relative to the first and second evaporators for guiding the web through the gap.

6. The vacuum coating apparatus of claim 1, wherein the first and second evaporators are arranged such that the first and second evaporation beams form a common deposition zone arranged between the first and second evaporators and the first and second coating drums.

7. The vacuum coating apparatus of claim 6, wherein the common deposition zone has a more uniform distribution of evaporated material than a deposition zone formed by a single evaporator when seen in a projection along the axes of the first and second coating drums.

8. The vacuum coating apparatus of claim 1, configured to convey a first web by the first coating drum through the gap and at the same time a second web by the second coating drum through the gap.

9. A vacuum coating apparatus for coating a web, comprising:
a vacuum chamber;
a first rotatable coating drum and a second rotatable coating drum disposed parallel to the first coating drum with a gap formed between the first and the second coating drums for transporting a web through the gap; and
at least a first evaporator comprising an evaporation source arranged next to the first coating drum and inclined towards the second coating drums for depositing a material onto the web when transported by the second coating drum, through the gap, the evaporation source of the first evaporator being arranged closer to the first coating drum than to the second coating drum and disposed relative to the first and second coating drums such that the gap is hidden from view by the first coating drum when seen from the evaporation source.

10. The vacuum coating apparatus of claim 9, further comprising at least a second evaporator comprising an evaporation source inclined towards the first coating drum for depositing a material onto the web when transported by the first coating drum, the second evaporator being arranged closer to the second coating drum than to the first coating drum and disposed relative to the first and second coating drums such that the gap is hidden from view by the second coating drum when seen from the evaporation source of the second evaporator.

11. The vacuum coating apparatus of claim 10, wherein the first evaporator comprises a first main evaporation direction and the second evaporator comprises a second main evaporation direction, the first main evaporation direction and the second main evaporation direction intersect at a point arranged behind the gap formed between the first and second coating drums.

12. The vacuum coating apparatus of claim 10, wherein each of the first and the second coating drums comprises a radius, and wherein the evaporation source of the first evaporator is spaced from the evaporation source of the second evaporator by a distance which is less than the radius of the coating drums.

13. The vacuum coating apparatus of claim 9, wherein the radius of the first and second coating drums is larger than the distance between the first coating drum and the evaporation source of the second evaporator and/or larger than the distance between the second coating drum and the evaporation source of the first evaporator.

14. A vacuum coating apparatus for coating a web, comprising:
a vacuum chamber;
at least one rotatable coating drum comprising an axis of rotation and a surface for transporting a web;
a first evaporator comprising at least one evaporation source; and
a second evaporator comprising at least one evaporation source, the first and second evaporators being arranged next to the coating drum and are inclined relative to each other when seen in a projection along the axis of the first coating drums.

15. The vacuum coating apparatus of claim 14, wherein:
the evaporation source of the first evaporator is adapted for generating a first evaporation beam comprising a first main evaporation direction; and
the evaporation source of the second evaporator is adapted for generating a second evaporation beam comprising a second main evaporation direction;
the first and the second evaporators being arranged such that their evaporation beams are inclined towards each other.

16. The vacuum coating apparatus of claim 15, wherein the first and the second evaporators being arranged such that the first main evaporation direction and the second main evaporation direction intersect at a point arranged between the coating drum and the first and second evaporators when seen in a projection parallel to the axis of rotation.

17. An evaporation unit, comprising:
a first evaporator comprising at least one evaporation source for generating a first evaporation beam;
a second evaporator comprising at least one evaporation source for generating a second evaporation beam; and
the first and the second evaporators being inclined relative to each other.

18. The evaporation unit of claim 17, further comprising:
a first row of first evaporators, each first evaporator being adapted to generate a first evaporation beam;
a second row of second evaporators, each second evaporator being adapted to generate a second evaporation beam, first and second rows being arranged parallel to each other; and
the first evaporators of the first row and the second evaporators of the second row being arranged such that the evaporation beams of the first evaporators are inclined relative to the evaporation beams of the second evaporators when seen in a projection along the first and second rows.

19. The evaporation unit of claim 18, wherein the first and second evaporators are arranged in a staggered manner.

20. A method for coating a web, comprising:
providing a first rotatable coating drum having an axis of rotation and a second rotatable coating drum having an axis of rotation disposed parallel to the first drum with a gap formed between the first and the second coating drums,
forming a common evaporation zone next to the surface of the first and second coating drums by evaporating material from a first evaporator from a first evaporation direction and evaporating a material from a second evaporator from a second evaporation direction, wherein the first and the second evaporators being inclined relative to each other when seen in a projection along the axis of the first and second coating drums; and
transporting at least one web by at least one of the first coating drum, the second coating drum, and a combination thereof through the common evaporation zone.
